(19) United States
(12) Patent Application Publication
(10) Pub. No.: US 2006/0199325 A1
(43) Pub. Date: Sep. 7, 2006

(54) Semiconductor integrated circuit device advantageous for microfabrication and manufacturing method for the same

(76) Inventors: Muneaki Maeno, Yokohama-shi (JP); Toshikazu Sei, Kawasaki-shi (JP)

Correspondence Address: DLA PIPER RUDNICK GRAY CARY US, LLP, 2000 UNIVERSITY AVENUE, E. PALO ALTO, CA, 94303-2248, US

(21) Appl. No.: 11/365,087

(22) Filed: Feb. 28, 2006

(30) Foreign Application Priority Data
Mar. 4, 2005 (JP) 2005-060433

(51) Int. Cl. H01L 21/8238; H01L 21/3205

(52) U.S. Cl. 438/199; 438/227; 438/229; 438/587

(57) ABSTRACT

A semiconductor integrated circuit device includes cells, each of the cells including a gate electrode, which is provided on the well, and first diffusion layers of a second conductivity type which are provided in the well such that the first diffusion layers sandwich the gate electrode, the first diffusion layers functioning as sources/drains. The device further includes sub-regions which are arranged in a non-occupied area of the logic circuit structure region, each of the sub-regions including a conductive layer, which is provided on the well and has the same pattern shape as the gate electrode, and second diffusion layers of the first conductivity type, which have the same pattern shape as the first diffusion layers and are disposed spaced apart to sandwich the conductive layer, the second diffusion layers being electrically connected to the well.

### CROSS-REFERENCE TO RELATED APPLICATIONS

This application is based upon and claims the benefit of priority from prior Japanese Patent Application No. 2005-060433, filed Mar. 4, 2005, the entire contents of which are incorporated herein by reference.

### BACKGROUND OF THE INVENTION

1. Field of the Invention

The present relates generally to a semiconductor integrated circuit device and a method of manufacturing the same, and relates, for example, to arrangements of sub-regions of basic cells and standard cells of application specific integrated circuits (ASICs) such as gate arrays and embedded arrays.

2. Description of the Related Art

In the prior art, diffusion layers (sub-regions) for fixing well potential are vertically disposed in advance on both sides of a macro-cell such as a standard cell, a gate array, an embedded array, thereby to prevent latch-up. However, since it is necessary to provide regions dedicated to sub-regions, the cell area in the vertical direction of the cell increases, leading to a bottleneck to the increase in integration density.

A solution to this problem is a semiconductor device wherein upper and lower sub-regions are eliminated and ordinary standard cells are disposed as dedicated cells in the same row in the areas of the sub-regions (see, for instance, Jpn. Pat. Appln. KOKAI Publication No. 2001-331294).

When a mask for cells in the deep sub-micron generation is to be formed, an optical proximity effect (OPE) occurs and a mask cannot faithfully be transferred to a glass substrate. It is thus necessary to perform optical proximity correction (OPC) in order to estimate the OPE and correct the mask pattern, thus obtaining a faithful pattern on the glass substrate.

In the structure disclosed in KOKAI No. 2001-331294, however, the pattern shapes of diffusion layers serving as sources/drains differ from the pattern shapes of diffusion layers serving as sub-regions. As a result, when the OPC is performed, the effect of the OPC differs at the peripheral parts of the sub-regions. Thus, the OPC cannot uniformly be performed within the chip.

Moreover, since the effect of OPC differs at the peripheral parts of the sub-regions, a hierarchical process, which can reduce the processing time in the OPC process, cannot be used, and the processing time of the OPC increases, resulting in an increase in manufacturing cost.

### BRIEF SUMMARY OF THE INVENTION

According to an aspect of the present invention, there is provided a semiconductor integrated circuit device comprising: cells which are arranged in an array in a logic circuit structure region of a well of a first conductivity type that is provided in a semiconductor substrate, each of the cells including a gate electrode, which is provided on the well, and first diffusion layers of a second conductivity type which are provided in the well such that the first diffusion layers sandwich the gate electrode, the first diffusion layers functioning as sources/drains; and sub-regions which are arranged in a non-occupied area of the logic circuit structure region, each of the sub-regions including a conductive layer, which is provided on the well and has the same pattern shape as the gate electrode, and second diffusion layers of the first conductivity type, which have the same pattern shape as the first diffusion layers and are disposed spaced apart to sandwich the conductive layer, the second diffusion layers being electrically connected to the well.

According to another aspect of the present invention, there is provided a semiconductor integrated circuit device comprising: cells which are arranged in an array in a logic circuit structure region of a well of a first conductivity type that is provided in a semiconductor substrate, each of the cells including a gate electrode, which is provided on the well, and first diffusion layers of a second conductivity type which are provided in the well such that the first diffusion layers sandwich the gate electrode, the first diffusion layers functioning as sources/drains; and second diffusion layers of the first conductivity type, which are provided in at least parts of the first diffusion layers functioning as the sources or in at least parts of the first diffusion layers in a non-occupied area, the second diffusion layers being electrically connected to the well and functioning as sub-regions.

According to still another aspect of the present invention, there is provided a method of manufacturing a semiconductor integrated circuit device, comprising: forming a first well of a first conductivity type and a second well of a second conductivity type in a semiconductor substrate; forming a first photoresist on the first well and the second well; forming a first photomask in which a plan-view pattern of a device region corresponding to a sub-region is identical to a plan-view pattern of a device region corresponding to a cell that is to be used as a logic circuit, by executing optical proximity correction; transferring the patterns of the first photomask to the first photoresist; performing anisotropic etching on the first well and the second well by using the first photomask with the transferred patterns as a mask, thus forming trenches; forming device isolation regions by burying insulation films in the trenches; forming a conductive layer on the first well and the second well; forming a second photoresist on the conductive layer; forming a second photomask in which a gate pattern corresponding to the sub-region is identical to a gate pattern corresponding to the cell, by executing optical proximity correction; transferring the gate patterns of the second photomask to the second photoresist; performing anisotropic etching down to a level of the first well and the second well by using the second photomask with the transferred gate patterns as a mask, thus leaving the conductive layer on the first well and the second well and forming gate patterns; forming a first diffusion layer of the first conductivity type, which functions as the sub-region, in a non-occupied area of the first well, and forming a second diffusion layer of the first conductivity type, which functions as a source/drain in the second well; and forming a third diffusion layer of the second conductivity type, which functions as a source/drain, in the first well, and a fourth diffusion layer of the second conductivity type, which functions as a sub-region in the second well.

### BRIEF DESCRIPTION OF THE SEVERAL VIEWS OF THE DRAWING

FIG. 1 is a plan view that shows a semiconductor integrated circuit device according to a first embodiment of the present invention;

FIG. 2 shows a photomask that is used in a fabrication step of the semiconductor integrated circuit device according to the first embodiment of the invention;

FIG. 3 illustrates a fabrication step of the semiconductor integrated circuit device according to the first embodiment of the invention;

FIG. 4 shows a photomask that is used in a fabrication step of the semiconductor integrated circuit device according to the first embodiment of the invention;

FIG. 5 illustrates a fabrication step of the semiconductor integrated circuit device according to the first embodiment of the invention;

FIG. 6 shows a photomask that is used in a fabrication step of the semiconductor integrated circuit device according to the first embodiment of the invention;

FIG. 7 illustrates a fabrication step of the semiconductor integrated circuit device according to the first embodiment of the invention;

FIG. 8 shows a photomask that is used in a fabrication step of the semiconductor integrated circuit device according to the first embodiment of the invention;

FIG. 9 is a plan view that shows a semiconductor integrated circuit device according to a modification of the present invention;

FIG. 10 shows a photomask that is used in a fabrication step of the semiconductor integrated circuit device according to the modification of the invention;

FIG. 11 illustrates a fabrication step of the semiconductor integrated circuit device according to the modification of the invention;

FIG. 12 shows a photomask that is used in a fabrication step of the semiconductor integrated circuit device according to the modification of the invention;

FIG. 13 is a plan view that shows a semiconductor integrated circuit device according to a second embodiment of the present invention;

FIG. 14 shows a photomask that is used in a fabrication step of the semiconductor integrated circuit device according to the second embodiment of the invention;

FIG. 15 shows a photomask that is used in a fabrication step of the semiconductor integrated circuit device according to the second embodiment of the invention;

FIG. 16 illustrates a fabrication step of the semiconductor integrated circuit device according to the second embodiment of the invention;

FIG. 17 shows a photomask that is used in a fabrication step of the semiconductor integrated circuit device according to the second embodiment of the invention;

FIG. 18 is a plan view that shows a semiconductor integrated circuit device according to a third embodiment of the present invention;

FIG. 19 is a schematic cross-sectional view of the structure of the device, taken along line A-A′ in FIG. 18;

FIG. 20 shows a photomask that is used in a fabrication step of the semiconductor integrated circuit device according to the third embodiment of the invention;

FIG. 21 illustrates a fabrication step of the semiconductor integrated circuit device according to the third embodiment of the invention;

FIG. 22 shows a photomask that is used in a fabrication step of the semiconductor integrated circuit device according to the third embodiment of the invention; and

FIG. 23 is a plan view that shows a semiconductor integrated circuit device according to a fourth embodiment of the present invention.

### DETAILED DESCRIPTION OF THE INVENTION

Embodiments of the present invention will now be described with reference to the accompanying drawings. In the description below, common parts in all the drawings are denoted by like reference numerals.

### First Embodiment

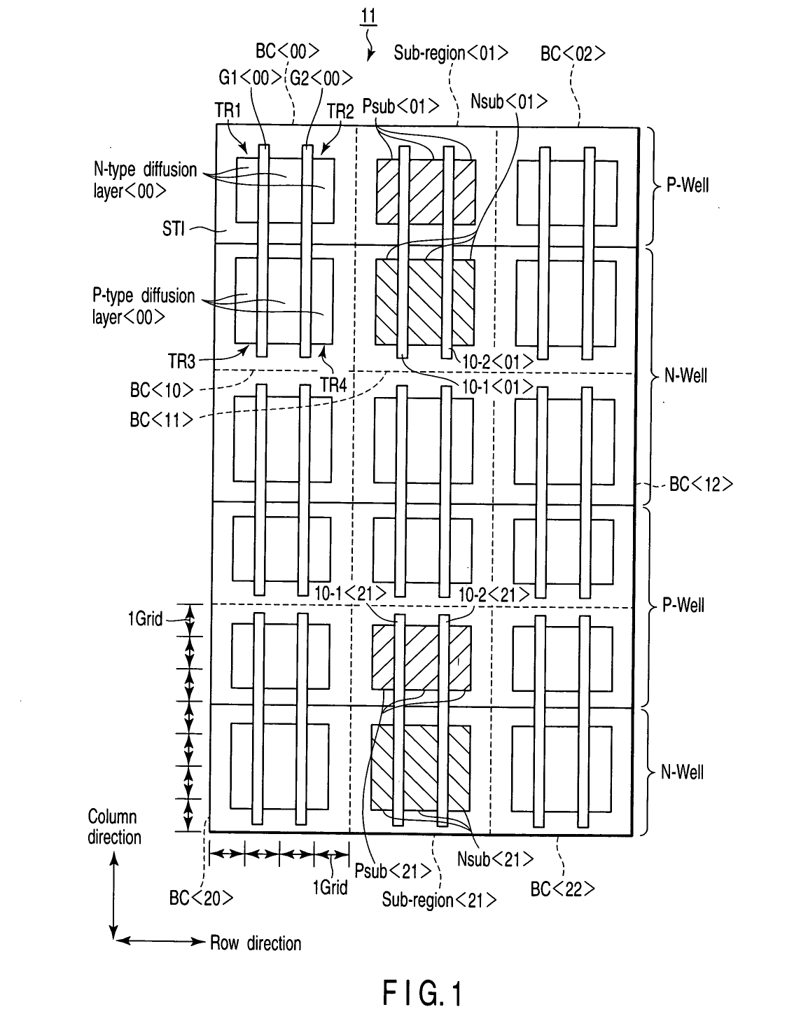

A semiconductor integrated circuit device according to a first embodiment of the present invention is described referring to FIG. 1. FIG. 1 is a plan view that schematically shows the semiconductor integrated circuit device according to the first embodiment. In FIG. 1, <nm> (m, n=a positive integer) corresponds to <row, column> of each of basic cells BC. The basic cells BC are cells in which the gate electrodes have the same pattern shape and the diffusion layers serving as sources/drains have the same pattern shape in a logic circuit structure region 11.

As is shown in FIG. 1, P-wells and N-wells are alternately provided in the column direction in a semiconductor substrate of the logic circuit structure region 11.

Basic cells BC <00> to BC <22> are regularly arrayed on the P-wells and N-wells in device regions. Further, signal lines and electrical systems are properly provided, and thus a desired circuit is formed. For example, a so-called CMOS inverter circuit can be formed by using a single basic cell BC <00>. In addition, a so-called CMOS flip-flop circuit can be formed by using basic cells BC <00> to BC <22> (excluding non-occupied regions <01> and <21>).

On the other hand, sub-regions are disposed in non-occupied regions <01> and <21> which are automatically detected as non-occupied regions and are not used as logic circuits.

Each of the basic cells BC <00> to BC <22> includes NMOS transistors TR1 and TR2 and PMOS transistors TR3 and TR4.

The basic cell BC <00> will now be described by way of example. The NMOS transistor TR1 includes a gate electrode G1 <00>, which is provided on the P-well so as to extend in the column direction, and N-type diffusion layers <00> which are provided in the P-well so as to sandwich the gate electrode G1 <00> and function as sources/drains.

The NMOS transistor TR2 neighbors the transistor TR1 in the row direction. The NMOS transistor TR2 includes a gate electrode G2 <00>, which is provided on the P-well so as to extend in the column direction, and N-type diffusion layers <00> which are provided in the P-well so as to sandwich the gate electrode G2 <00> and function as sources/drains. One of these N-type diffusion layers <00> is shared by the transistor TR1.

The PMOS transistor TR3 includes a gate electrode G1 <00>, which is provided on the N-well so as to extend in the column direction, and P-type diffusion layers <00> which are provided in the N-well so as to sandwich the gate electrode G1 <00> and function as sources/drains.

The PMOS transistor TR4 neighbors the transistor TR3 in the row direction. The PMOS transistor TR4 includes a gate electrode G2 <00>, which is provided on the N-well so as to extend in the column direction, and P-type diffusion layers <00> which are provided in the N-well so as to sandwich the gate electrode G2 <00> and function as sources/drains. One of these P-type diffusion layers <00> is shared by the transistor TR3.

The gate electrode G1 <00> extends in the column direction and is shared by the transistors TR1 and TR3. The gate electrode G2 <00> extends in the column direction and is shared by the transistors TR2 and TR4.

The other basic cells BC <02> to BC <22> have the same structure as described above.

Each of the sub-regions <01> and <21> includes diffusion layers Psub and Nsub, which have the same pattern shapes as the N-type diffusion layers and P-type diffusion layers that function as the sources/drains of the basic cells BC <00> to BC <22>, and also includes conductive layers 10-1 and 10-2 which have the same pattern shapes as the gate electrodes G1 and G2. The conductivity type of the diffusion layer Psub, Nsub is opposite to that of the diffusion layer of the basic cell BC on the same well (i.e. the same conductivity type as the well). A predetermined voltage (e.g. VSS, VDD) is applied to the diffusion layers Psub and Nsub, and thereby the diffusion layers Psub and Nsub are electrically connected to the P-well and N-well, respectively.

For example, the sub-region <01> includes diffusion layers Psub <01> and Nsub <01>, which have the same pattern shapes as the N-type diffusion layers <00> and P-type diffusion layers <00> that function as the sources/drains of the basic cell BC <00>, and also includes conductive layers 10-1 <01> and 10-2 <01> which have the same pattern shapes as the gate electrodes G1 and G2.

As is shown in FIG. 1, the pattern shapes of the gate electrodes and sources/drains of the basic cell, BC <00> to BC <22>, have a mirror-image relationship to the neighboring basic cell or the neighboring sub-region <01>, <21>. Similarly, the pattern shapes of the conductive layers and diffusion layers of the sub-region <01>, <21> have a mirror-image relationship to the neighboring cell or neighboring sub-region.

<Manufacturing Method>

A method of manufacturing the semiconductor integrated circuit device according to the present embodiment will now be described by taking the semiconductor integrated circuit device shown in FIG. 1 by way of example.

To start with, P-type and N-type impurities are doped in the semiconductor substrate in the row direction by means of, e.g. ion implantation. The impurities are thermally diffused to form P-wells and N-wells. A photoresist is coated on the semiconductor substrate in which the P-wells and N-wells are formed (not illustrated).

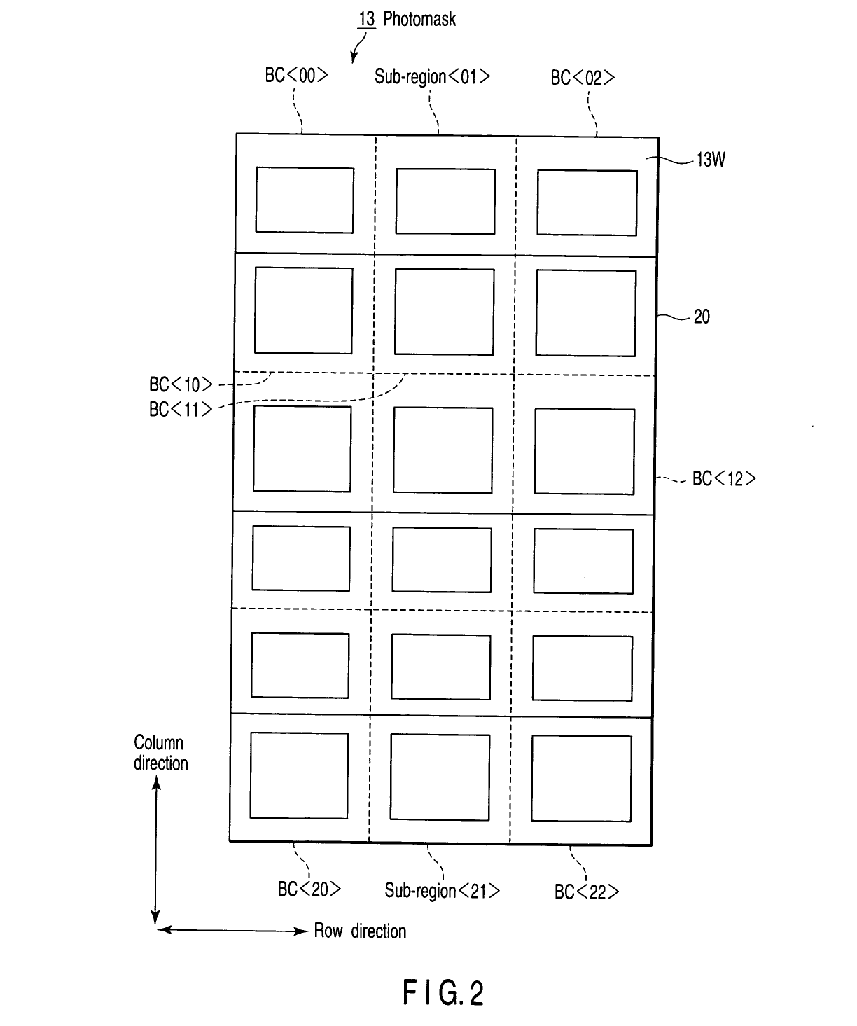

Subsequently, a photomask 13, as shown in FIG. 2, is formed. The photomask 13 has opening portions 13W at areas above regions which will become device isolation regions STI. When the mask 13 is formed, an optical proximity effect (OPE) occurs, which prevents faithful transfer of a mask pattern to a glass substrate 20. To avoid this problem, the OPE is estimated in advance and the mask pattern is corrected. Thereby, optical proximity correction (OPC) is performed to obtain a faithful pattern on the substrate. It is desirable to perform OPC with the highest precision, since the photomask 13 determines the gate width of the device region and directly affects the performance of the transistors.

As is shown in FIG. 2, the pattern shape of the mask 13 is determined, for example, such that formation areas of the sub-regions <01> and <21> have the same pattern shapes as formation areas of the basic cells BC <02> to BC <22>. Thus, regardless of the formation areas of the sub-regions and the formation areas of the basic cells BC, the OPC is uniformly performed.

Subsequently, the pattern of the photomask 13 is transferred to the photoresist.

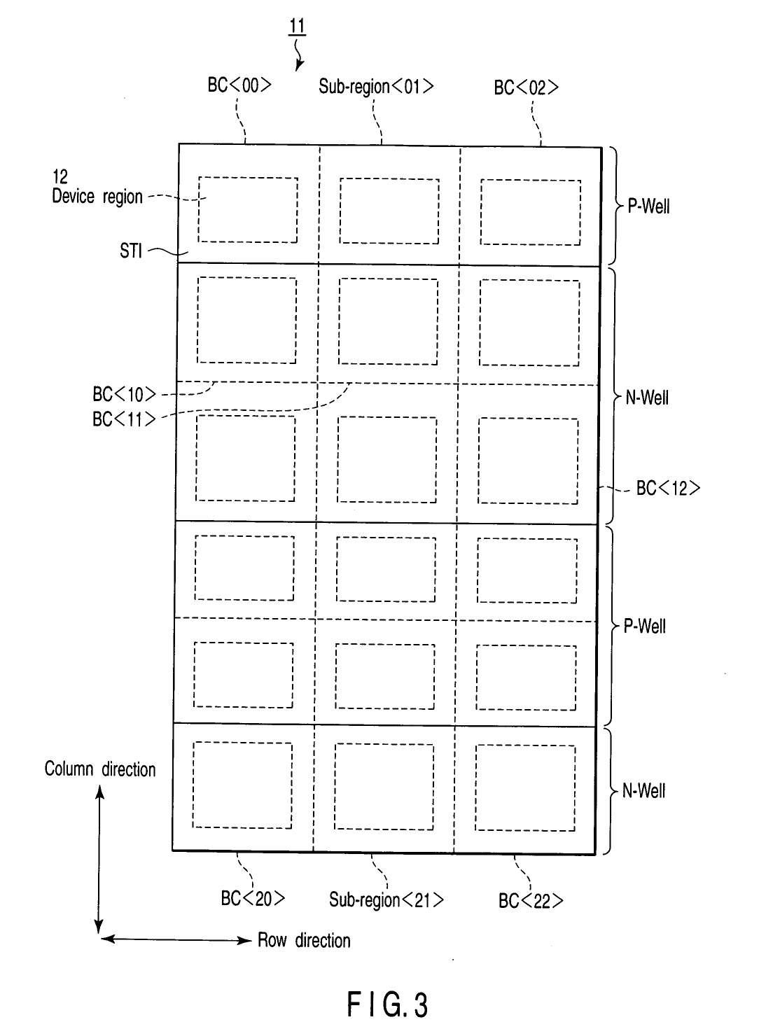

Then, as shown in FIG. 3, using as a mask the photoresist having the transferred pattern of the photomask 13, anisotropic etching, such as RIE (Reactive Ion Etching), is performed on the semiconductor substrate, and trenches are formed. The photoresist is then removed. A silicon oxide film (SiO₂) is deposited on the substrate by, e.g. CVD (Chemical Vapor Deposition). The silicon oxide film is planarized by, e.g. CMP (Chemical Mechanical Polishing) down to a level of the surface of the substrate, and the silicon oxide film is buried in the trenches. Thus, device isolation regions STI are formed.

Following the above, using, e.g. CVD, a polysilicon is deposited. A photoresist is coated on the polysilicon (not illustrated).

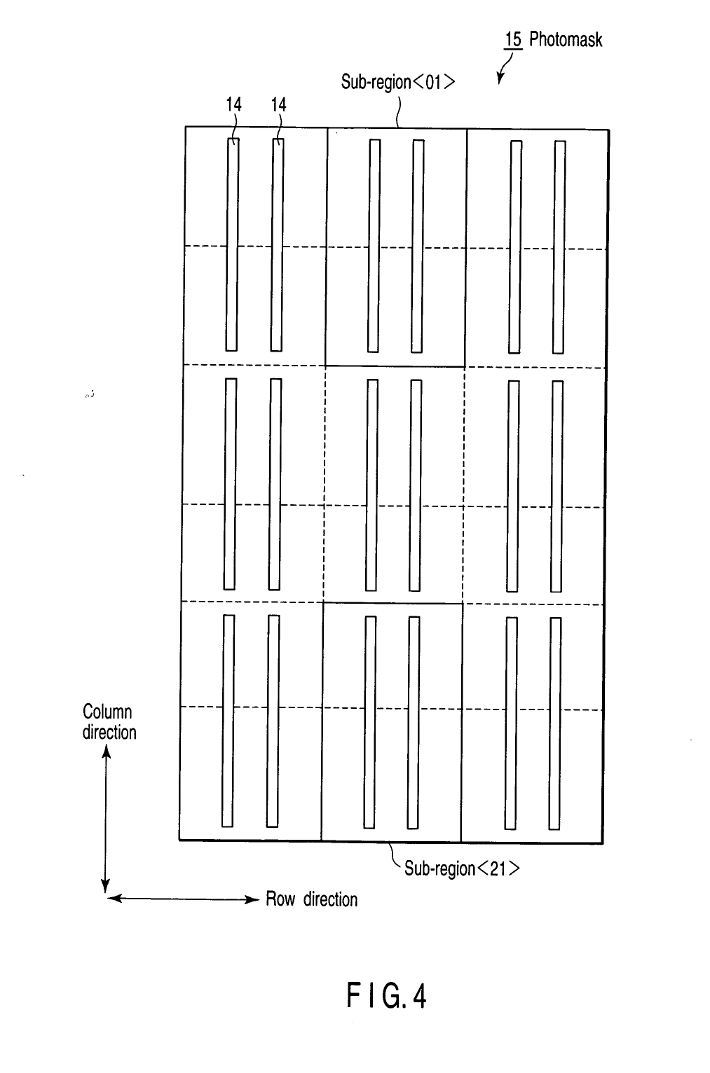

Then, as shown in FIG. 4, a photomask 15 is formed. The photomask 15 has pattern shapes 14 for forming gate electrodes, and is used to transfer the pattern shapes to the photoresist. When the photomask 15 is formed, optical proximity correction (OPC) is performed in the same manner as described above. Since the gate patterns directly affect the performance of transistors, it is desirable to perform the OPC with the highest dimensional precision.

As is shown in FIG. 4, the photomask 15 is patterned, for example, such that the formation areas of the sub-regions <01> and <21> have the same gate pattern shapes as the formation areas of the basic cells BC <02> to BC <22>. Thus, regardless of the formation areas of the sub-regions and the formation areas of the basic cells BC, the OPC is uniformly performed.

Subsequently, using the photomask 15 as a mask, the photoresist is subjected to exposure and development, and the pattern shapes 14 corresponding to the gate electrodes are transferred to the photoresist.

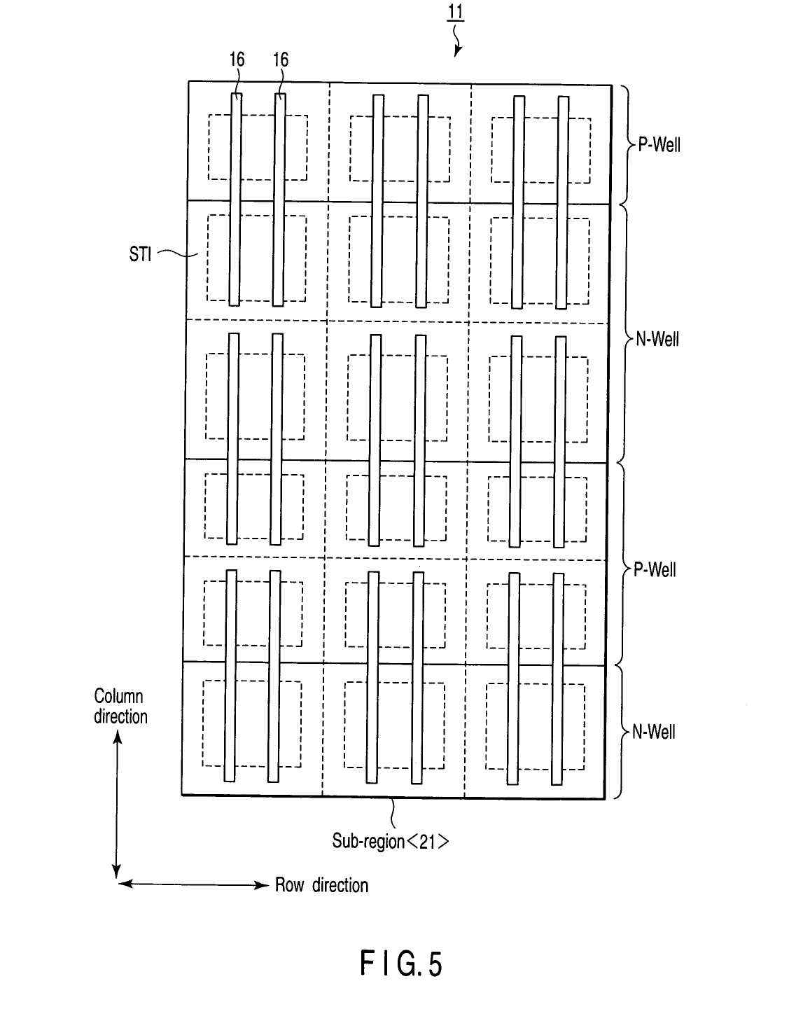

Then, as shown in FIG. 5, using the photoresist with the transferred pattern as a mask, anisotropic etching, such as RIE, is performed down to a level of the surface of the substrate, and the polysilicon is left on the substrate. Thereafter, the photoresist is removed by means of, e.g. an asher. Through the above fabrication steps, gate patterns 16 are formed in the logic circuit structure region 11.

Following the above, a photoresist is coated on the entire surface of the logic circuit structure region 11 in which the gate patterns 16 are formed (not illustrated).

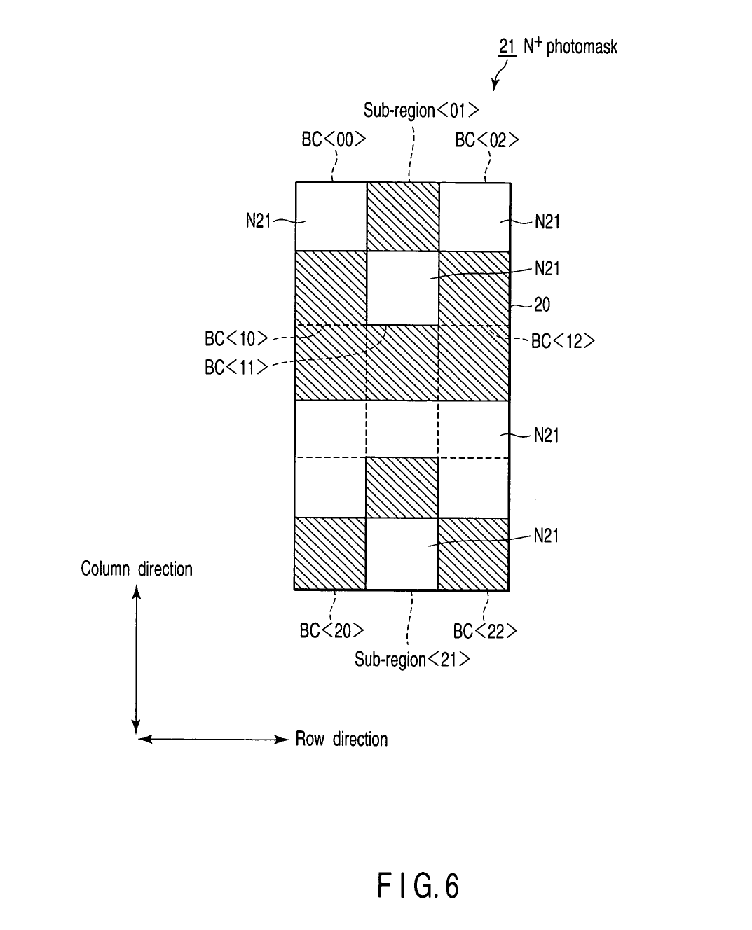

Then, as shown in FIG. 6, an N⁺ photomask 21 is formed and patterned. The N⁺ photomask 21 has, on a glass substrate 20, opening portions N21 corresponding to formation areas of the N-type diffusion layers of the basic cells BC and the diffusion layers Nsub <01> and Nsub <21>, and the N⁺ photomask 21 is used to transfer this pattern to the photoresist. When the photomask 21 is formed, there is no need to perform the OPC.

Using the N⁺ photomask 21 as a mask, the photoresist is subjected to exposure and development, and the pattern of the photomask 21 is transferred to the photoresist.

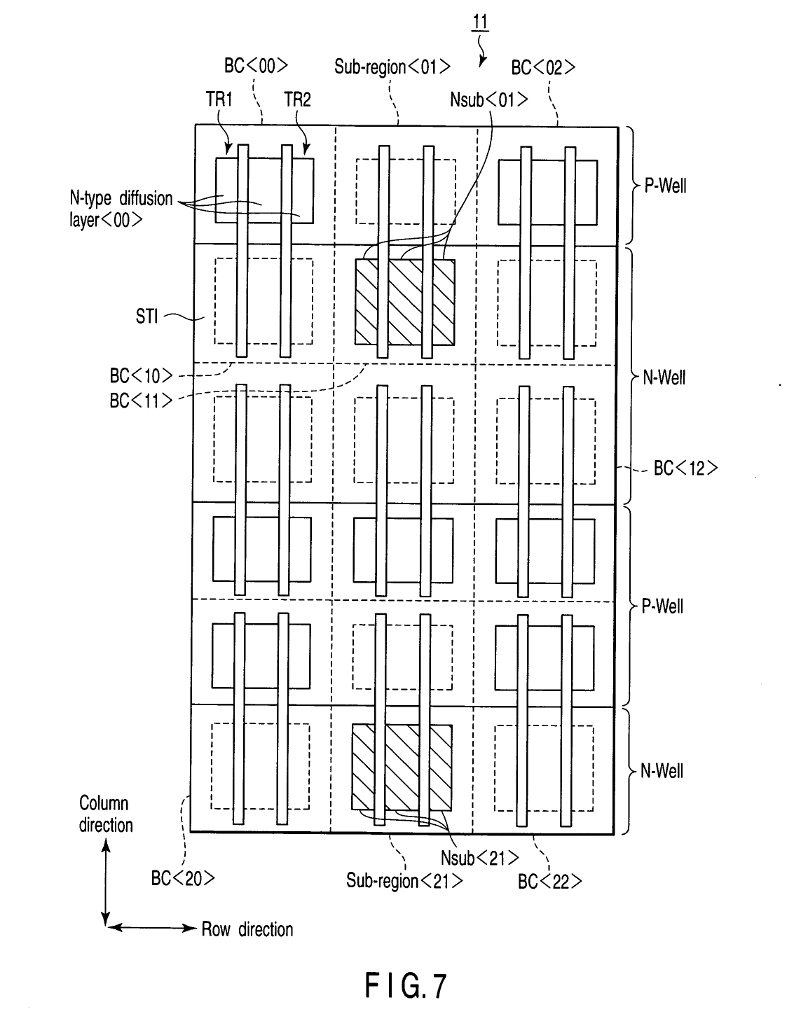

Subsequently, as shown in FIG. 7, using the photoresist with the transferred pattern as a mask, N-type impurities, such as phosphorus (P), are implanted by, e.g. ion implantation, and the implanted impurities are thermally diffused. N-type diffusion layers, which function as sources/drains, and N-type diffusion layers Nsub <01> and Nsub <21>, which function as sub-regions, are formed in a self-alignment manner using the device isolation regions STI and the gate patterns. The photoresist is then removed.

A photoresist is further coated on the logic circuit structure region 11 (not illustrated).

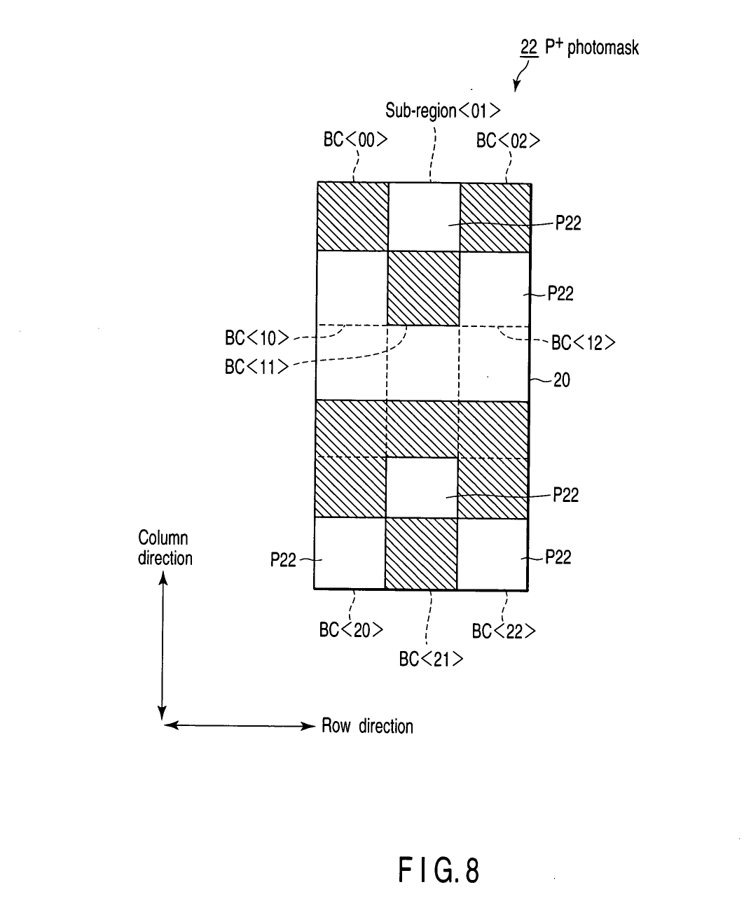

Then, as shown in FIG. 8, a P⁺ photomask 22 is formed and patterned. The P⁺ photomask 22 has, on a glass substrate 20, opening portions P22 corresponding to formation areas of the P-type diffusion layers of the basic cells BC and the diffusion layers Psub <01> and Psub <21>, and the P⁺ photomask 22 is used to transfer this pattern to the photoresist. When the photomask 22 is formed, there is no need to perform the OPC, as in the case of the formation of the N⁺ photomask 21.

Subsequently, using the photoresist with the transferred pattern as a mask, P-type impurities, such as boron (B), are implanted by, e.g. ion implantation, and the implanted impurities are thermally diffused. P-type diffusion layers, which function as sources/drains, and P-type diffusion layers Psub <01> and Psub <21>, which function as sub-regions, are formed in a self-alignment manner using the device isolation regions STI and the gate patterns. The photoresist is then removed, and the semiconductor integrated circuit device shown in FIG. 1 is fabricated.

As has been described above, in the semiconductor integrated circuit device according to the present embodiment, the sub-region <01> and sub-region <21> are disposed in the non-occupied regions <01> and <21> so as to have the same pattern shapes as the basic cells BC. Thus, there is no need to prepare dedicated regions for the sub-regions.

Since the areas for the dedicated regions are not necessary, the integration density can advantageously be increased. For example, in the case of the structure wherein a dedicated area for a sub-region, which is provided between upper and lower basic cells that neighbor the sub-region in the column direction, is prepared in advance, the sub-region is shared by the upper and lower basic cells. Thus, the sub-region occupies a ½ grid and another ½ grid, that is, 1 grid in total in the unit cell. Assume now that the vertical cell dimension of the basic cell is 8 grids, the horizontal cell dimension is 4 grids, and the grid size is A μm. In this case, the cell size of the basic cell is 8×A×4×A=32×A² μm², and the occupied area of the sub-region is 1×A×4×A=4×A² μm². The ratio of the occupied area of the sub-region to the cell size is 4×A² μm²/32×A² μm²=0.125, i.e. about 12.5%. Therefore, in the semiconductor integrated circuit device according to this embodiment, this occupied area can be eliminated. Accordingly, the occupied area of about 12.5% can be reduced per unit cell.

The sub-region <01> and sub-region <21> include the diffusion layers Psub and diffusion layers Nsub, which have the same pattern shapes as the N-type diffusion layers and P-type diffusion layers serving as sources/drains.

Thus, when the OPC is performed to form the photomask 13, the OPC can advantageously be uniformly performed on the regions which become the basic cells BC and sub-regions.

Furthermore, the sub-region <01> and sub-region <21> include the conductive layers 10-1 and 10-2 having the same pattern shapes as the gate electrodes G1 and G2.

Thus, when the OPC is performed to form the photomask 15, the OPC can advantageously be uniformly performed on the regions which become the basic cells BC and sub-regions.

A predetermined voltage is applied to the diffusion layers Psub and diffusion layers Nsub, and the diffusion layers Psub and diffusion layers Nsub are electrically connected to the P-wells and N-wells. Thus, the voltage at the P-wells and N-wells can be fixed, and the well voltage can advantageously be stabilized.

As has been described above, according to the method of manufacturing the semiconductor integrated circuit device of the present embodiment, the pattern shape of the photomask 13 is formed, for example, such that the formation areas of the sub-region <01> and sub-region <21> and the formation areas of the basic cells BC <02> to BC <22> have the same pattern shapes, and the photomask 13 is subjected to the OPC. Thus, the OPC can uniformly be performed on the formation areas of the sub-regions and the formation areas of the basic cells BC, and the yield can advantageously be increased.

Further, the OPC is performed on the photomask 15 having the same gate pattern shapes on the formation areas of the sub-region <01> and sub-region <21> and the formation areas of the basic cells BC <02> to BC <22>. Thus, the OPC can uniformly be performed on the gate pattern shapes, and the desired gate pattern shapes can be obtained. Therefore, the yield can advantageously be increased.

As described above, since the pattern shapes corresponding to the device regions are the same and the gate pattern shapes are the same, a so-called hierarchical process, which can reduce the processing time, can be executed in the OPC process. Thus, the time for the OPC can be reduced, and the time for generating mask data for forming the mask can be reduced. Therefore, the cost of the mask can advantageously be reduced.

[Modification]

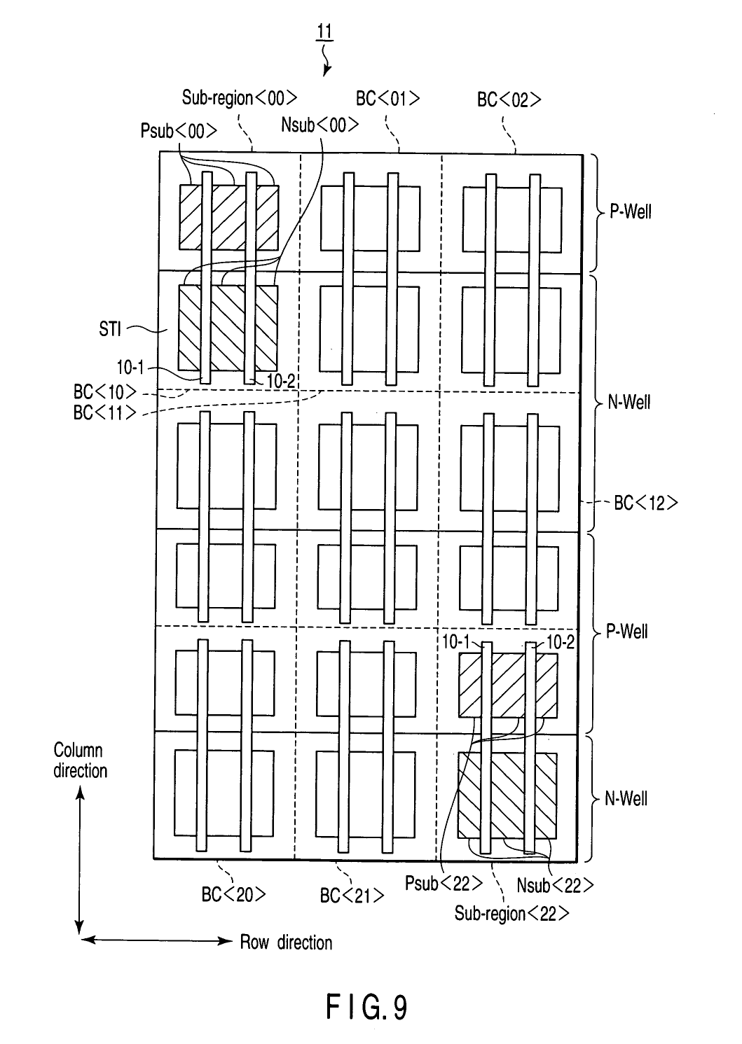

Next, a semiconductor integrated circuit device according to a modification of the present invention is described referring to FIG. 9. This modification relates to a case where circuit alternation is made in the logic circuit structure region 11 shown in FIG. 1. A description of parts common to those in the first embodiment is omitted.

As is shown in FIG. 9, the semiconductor integrated circuit device of this modification differs from that of the first embodiment in that sub-regions <00> and <22> are disposed in non-occupied regions <00> and <22>, which are not used as logic circuits, and regions <01> and <21> are used as logic circuits.

According to the semiconductor integrated circuit device of the modification, the same advantageous effects as in the first embodiment are obtained. Further, the sub-regions <00> and <22> are disposed in the non-occupied regions <00> and <22> which are not used for the logic circuit. This configuration may be adopted where necessary.

A method of manufacturing the semiconductor integrated circuit device according to the modification will now be described by taking the semiconductor integrated circuit device shown in FIG. 9 by way of example.

To start with, using the same fabrication steps as in the first embodiment, N-wells, P-wells and device isolation regions STI are formed in the semiconductor substrate. Gate patterns are then formed on the substrate. Further, a photoresist is coated on the entire surface of the resultant structure (not illustrated).

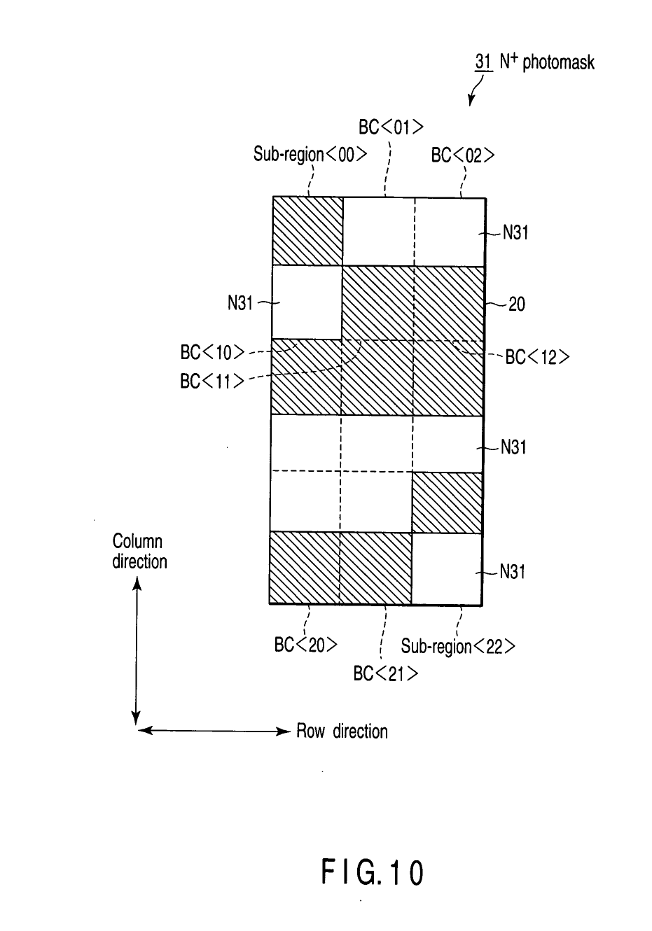

Then, as shown in FIG. 10, an N⁺ photomask 31 is formed and patterned. The N⁺ photomask 31 has, on a glass substrate 20, opening portions N31 corresponding to formation areas of the N-type diffusion layers of the basic cells BC and the diffusion layers Nsub <00> and Nsub <22>, and the N⁺ photomask 31 is used to transfer this pattern to the photoresist. When the photomask 31 is formed, there is no need to perform the OPC.

Using the N⁺ photomask 31 as a mask, the photoresist is subjected to exposure and development, and the pattern of the photomask 31 is transferred to the photoresist.

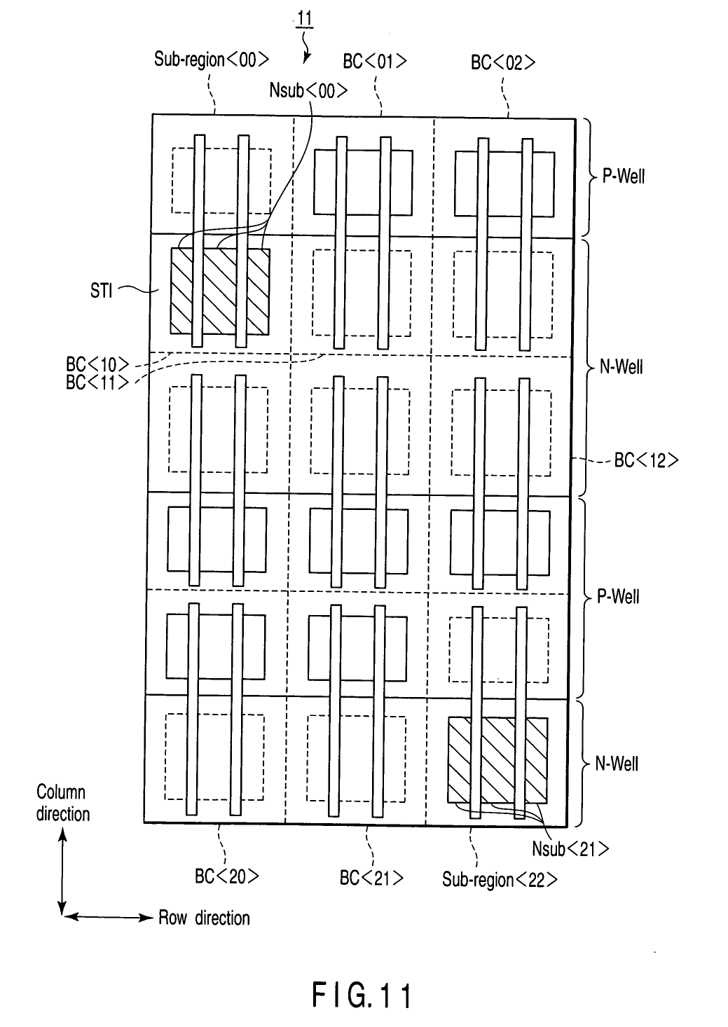

Subsequently, as shown in FIG. 11, using the photoresist with the transferred pattern as a mask, N-type impurities, such as phosphorus (P), are implanted by, e.g. ion implantation, and the implanted impurities are thermally diffused. Thus, N-type diffusion layers of the basic cells BC and N-type diffusion layers Nsub <00> and Nsub <22> are formed. The photoresist is then removed.

A photoresist is further coated on the entire surface of the logic circuit structure region 11 (not illustrated).

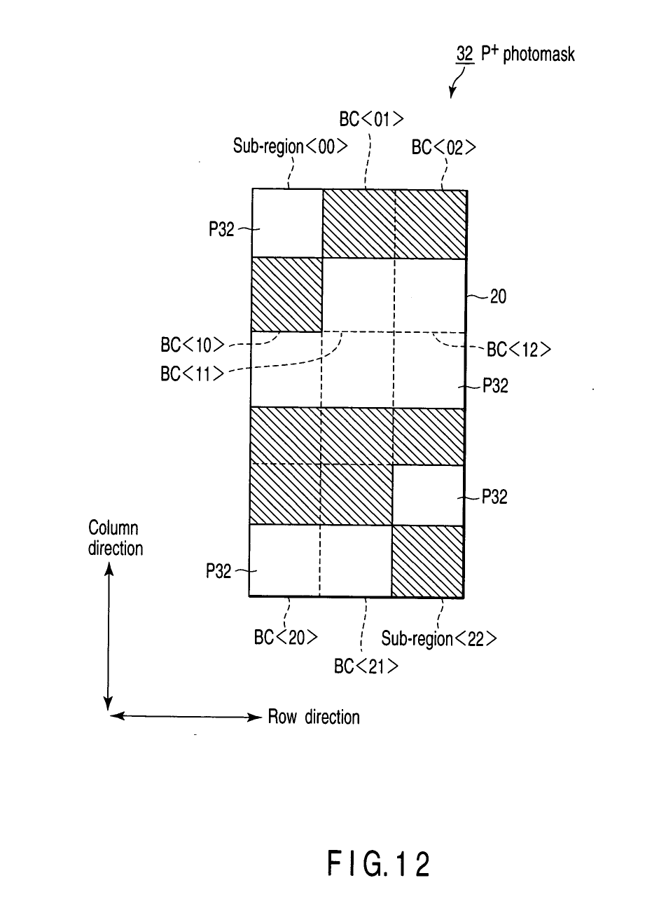

Then, as shown in FIG. 12, a P⁺ photomask 32 is formed and patterned. The P⁺ photomask 32 has, on a glass substrate 20, opening portions P32 corresponding to formation areas of the P-type diffusion layers of the basic cells BC and the diffusion layers Psub <00> and Psub <22>, and the P⁺ photomask 32 is used to transfer this pattern to the photoresist. When the photomask 32 is formed, there is no need to perform the OPC.

With the photomask 32 used as a mask, the photoresist is exposed and developed. Thus, the pattern of the photomask 32 is transferred to the photoresist.

Subsequently, using the photoresist with the transferred pattern as a mask, P-type impurities, such as boron (B), are implanted by, e.g. ion implantation, and the implanted impurities are thermally diffused. P-type diffusion layers and sub-regions Psub <00> and Psub <22> are formed. The photoresist is then removed, and the semiconductor integrated circuit device shown in FIG. 9 is fabricated.

According to the above-described method of manufacturing the semiconductor integrated circuit device of the modification, the same advantageous effects as in the first embodiment can be obtained. Further, by altering only the patterns of the photomasks 31 and 32, it becomes possible to execute an ECO (Engineering Change Order) process for altering the logic circuit in accordance with clients' requests, without altering the mask patterns for the device isolation regions STI, gate patterns, etc., while the sub-regions <00> and <22> are secured. Therefore, the circuit alteration can advantageously be performed without increasing the time for fabrication.

Furthermore, when the ECO process is executed, there is no need to perform OPC on the photomasks 31 and 32 that are to be altered. Thus, the manufacturing cost of the photomasks 31 and 32 can be reduced to, e.g. about ⅕, compared to the manufacturing cost of the mask 13 and 15 that require execution of OPC. Therefore, the manufacturing cost at the time of circuit alteration can advantageously be reduced.

### Second Embodiment

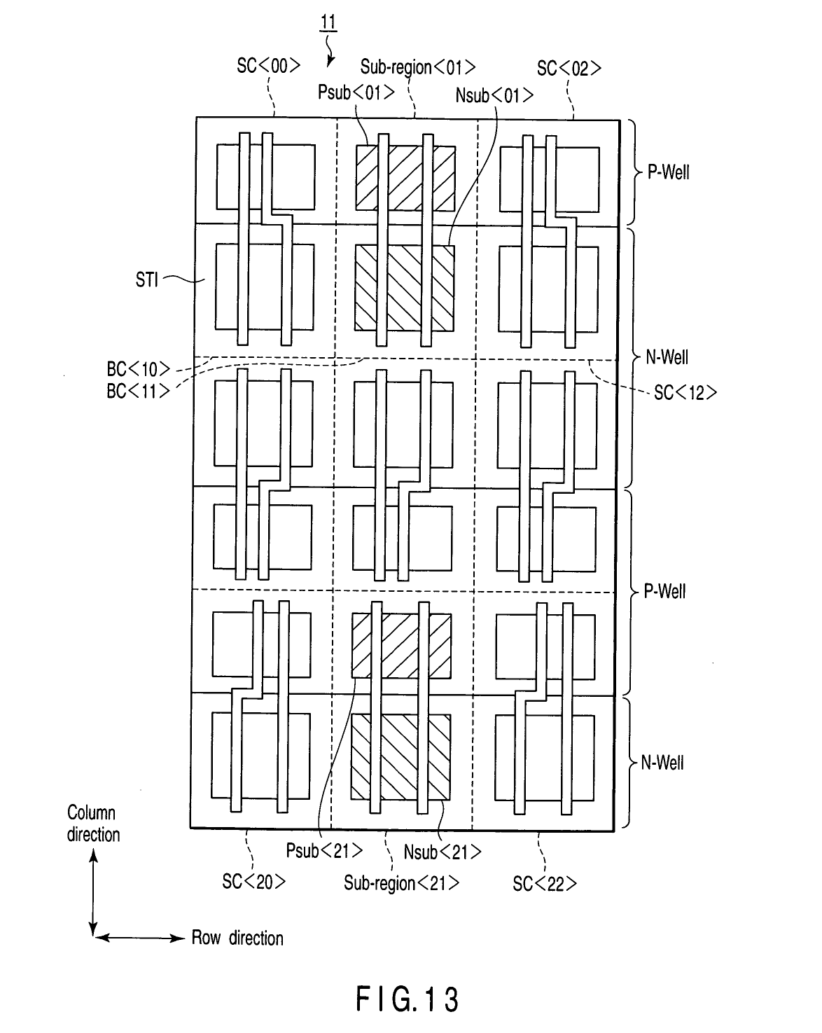

A semiconductor integrated circuit device according to a second embodiment of the present invention will now be described with reference to FIG. 13. A description of parts common to those in the first embodiment is omitted. In the first embodiment, the basic cell BC, which is disposed in the non-occupied area and is not used for the logic circuit, is used as the sub-region. In the second embodiment, the non-occupied area is used as a sub-region for standard cells SC.

The standard cells, in this context, refer to cells in which the pattern shapes of at least gate electrodes are different between the cells or are identical. However, for example, the cells may have different occupied areas.

As is shown in FIG. 13, sub-regions <01> and <21>, which have the same pattern shapes as the above-described basic cells BC, are provided in the non-occupied regions <01> and <21> which are not used as logic circuits.

According to the semiconductor integrated circuit device of this embodiment, the same advantageous effects as in the first embodiment are obtained. Further, the sub-regions <01> and <21>, which have the same pattern shapes as the basic cells, are disposed in the non-occupied regions <01> and <21> which are not used for logic circuits. This configuration may be adopted where necessary.

Next, a method of manufacturing the semiconductor integrated circuit device according to the second embodiment is described.

To start with, using the same fabrication steps as in the first embodiment, N-wells, P-wells and device isolation regions STI are formed in the semiconductor substrate. A polysilicon, for instance, is deposited on the semiconductor substrate by means of, e.g. CVD. A photoresist is coated on the polysilicon (not illustrated).

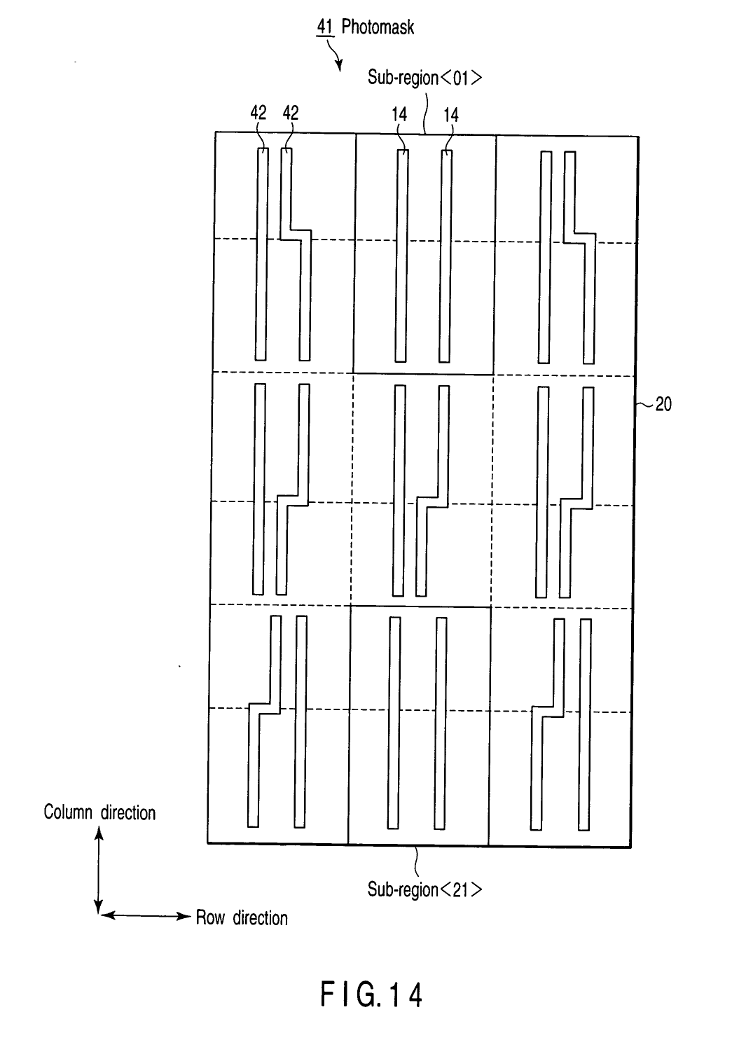

Then, as shown in FIG. 14, a photomask 41 is formed. The photomask 41 has pattern shapes 42 for forming gate electrodes, and is used to transfer the pattern shapes 42 to the photoresist. When the photomask 41 is formed, optical proximity correction (OPC) is performed with the highest dimensional precision in the same manner as described above.

As is shown in FIG. 14, gate pattern shapes 14 of the sub-regions <01> and <21>, which have the same pattern shapes as the above-described basic cells BC, are formed at the same time in the vicinity of the formation regions of the standard cells SC. Thus, OPC is uniformly performed.

Subsequently, using the photomask 41 as a mask, the photoresist is subjected to exposure and development, and the pattern shapes 42 and 14 corresponding to the gate electrodes are transferred to the photoresist.

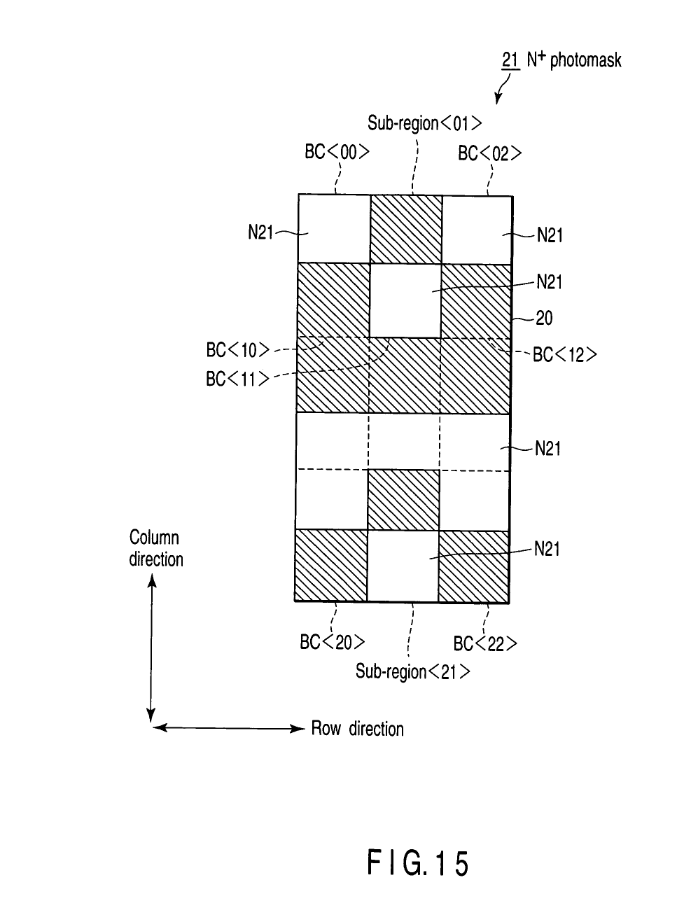

Then, as shown in FIG. 15, an N⁺ photomask 21 is formed and patterned. The N⁺ photomask 21 has, on a glass substrate 20, opening portions N21 corresponding to formation areas of the N-type diffusion layers of the standard cells SC and the sub-regions Nsub <01> and Nsub <21>, and the N⁺ photomask 21 is used to transfer this pattern to the photoresist. When the photomask 21 is formed, there is no need to perform the OPC.

Using the N⁺ photomask 21 as a mask, the photoresist is subjected to exposure and development, and the pattern of the photomask 21 is transferred to the photoresist.

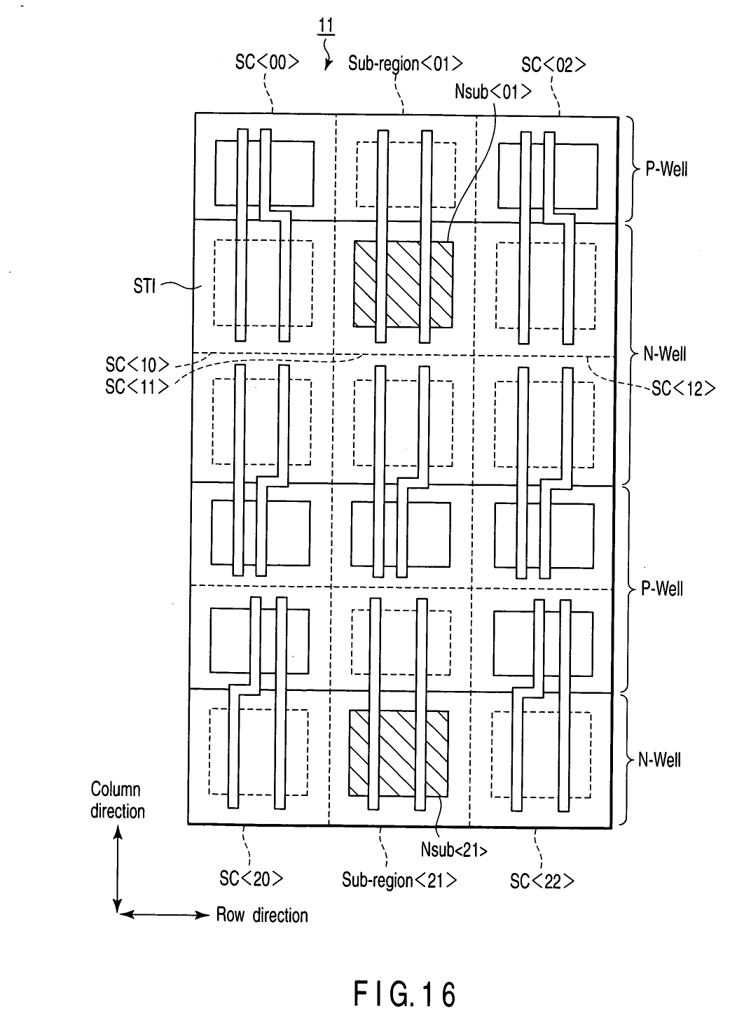

Subsequently, as shown in FIG. 16, using the photoresist with the transferred pattern as a mask, N-type impurities, such as phosphorus (P), are implanted by, e.g. ion implantation, and the implanted impurities are thermally diffused. N-type diffusion layers of the standard cells SC and N-type diffusion layers Nsub <01> and Nsub <21> are formed. The photoresist is then removed.

A photoresist is further coated on the logic circuit structure region 11 (not illustrated).

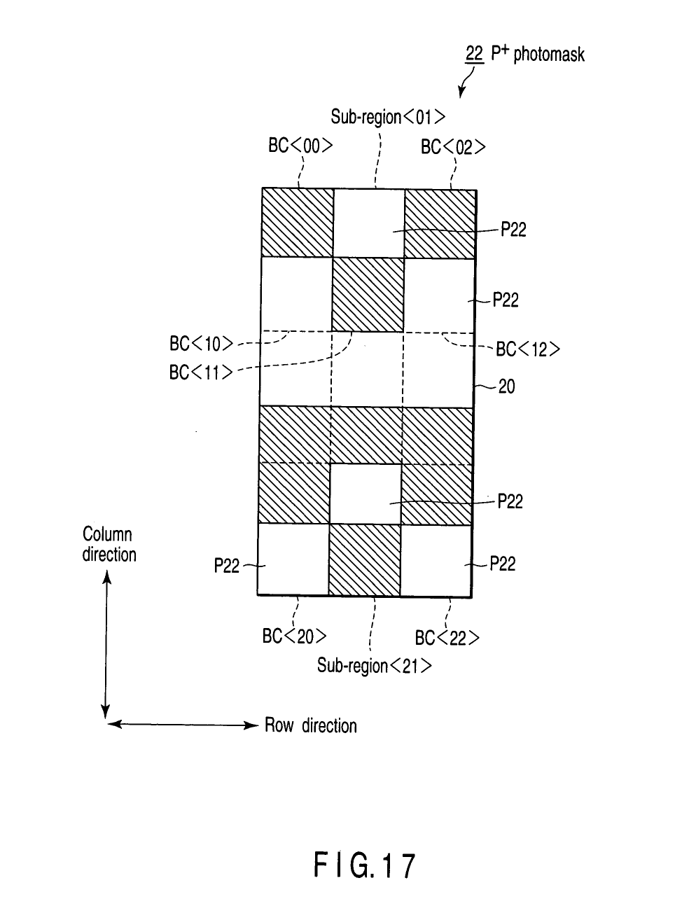

Then, as shown in FIG. 17, a P⁺ photomask 22 is formed and patterned. The P⁺ photomask 22 has, on a glass substrate 20, opening portions P22 corresponding to formation areas of the P-type diffusion layers of the standard cells SC and the sub-regions Psub <01> and Psub <21>, and the P⁺ photomask 22 is used to transfer this pattern to the photoresist. When the photomask 22 is formed, there is no need to perform the OPC.

Subsequently, using the photomask 22 as a mask, the photoresist is subjected to exposure and development and the pattern of the photomask 22 is transferred.

Then, using the photoresist with the transferred pattern as a mask, P-type impurities, such as boron (B), are implanted by, e.g. ion implantation, and the implanted impurities are thermally diffused. P-type diffusion layers and sub-regions Psub <01> and Psub <21> are formed. The photoresist is then removed, and the semiconductor integrated circuit device shown in FIG. 13 is fabricated.

According to the above-described method of manufacturing the semiconductor integrated circuit device of this modification, the same advantageous effects as in the first embodiment can be obtained. Further, when the photomask 41 is formed, the gate patterns 14, which are the same as the gate patterns of the basic cells BC, are formed in the non-occupied regions <01> and <21> at the same time as the gate patterns 42 of the standard cells SC.

If the OPC is performed in the state in which the gate patterns 14 are not present in the non-occupied areas <01> and <21>, a greater degree of optical proximity effect (OPC) would occur in the vicinity of the non-occupied areas than in the state in which the gate patterns 14 are present, and a greater degree of correction of the mask pattern would be required. Consequently, the gate width of the device region of the standard cell SC is adversely affected, and desired performance of the transistors cannot be obtained.

In the present embodiment, however, when the photomask 41 is formed, OPC is performed in the state in which the gate patterns 14 are “present” in the non-occupied areas <01> and <21>. Thus, the degree of correction of the mask pattern can be reduced, and the gate width of the device region of the standard cell SC can be made uniform, and the desired performance of the transistors can advantageously be obtained.

As regards the sub-regions <01> and <21>, if the photomasks 21 and 22 and masks (not shown) for a fabrication step of contact formation and for subsequent steps are altered and diffusion layers and signal wiring lines are altered, these sub-regions can be used as ordinary basic cells BC. Thus, the ECO process for altering the logic circuit can be performed, and the circuit alteration can advantageously be easily performed. Moreover, when the photomasks 21 and 22 are formed, there is no need to perform OPC. Therefore, the manufacturing cost does not increase, compared to the case of executing alterations including alteration of pattern masks for device isolation regions STI and gate patterns.

### Third Embodiment

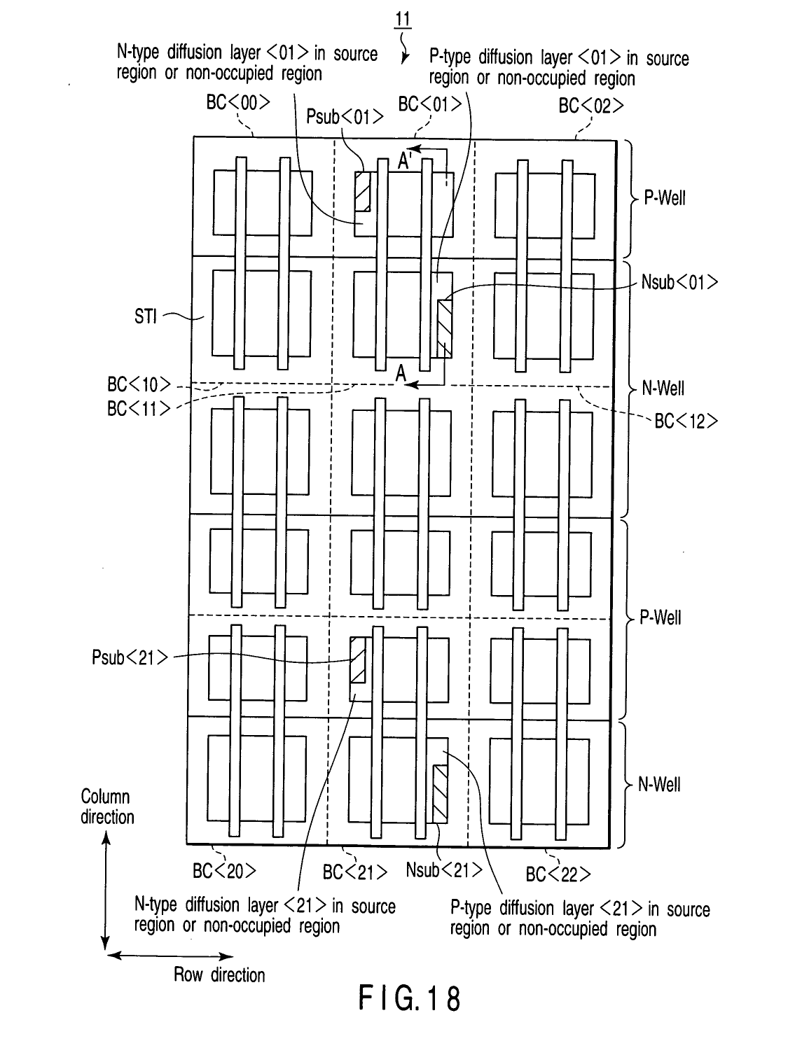

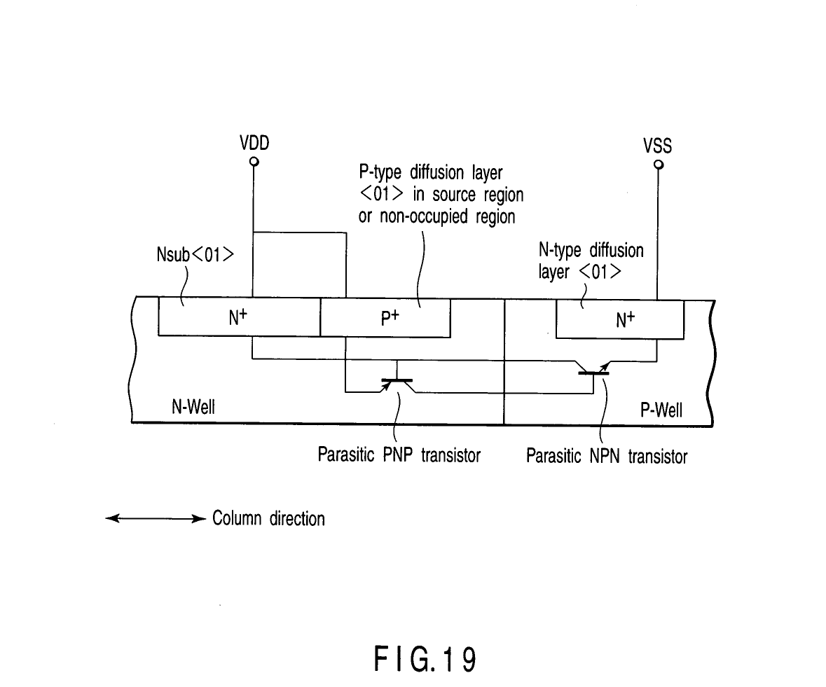

Next, a semiconductor integrated circuit device according to a third embodiment of the invention is described referring to FIG. 18 and FIG. 19. A description of parts common to those of the first embodiment is omitted. FIG. 18 is a plan view that shows the semiconductor integrated circuit device according to the third embodiment. FIG. 19 is a schematic cross-sectional view of the structure of the device, taken along line A-A′ in FIG. 18.

As is shown in FIG. 18, basic cells BC <00> to BC <22> are arrayed in the entire surface of the logic circuit structure region 11. Sub-regions are provided in source regions of the basic cells BC or in diffusion layers of non-occupied areas. Each sub-region has a conductivity type that is opposite to the conductivity type of the diffusion layer (i.e. the same conductivity type as the well). The pattern shapes of the gate electrodes and source/drain regions of the basic cell, BC <00> to BC <22>, have a mirror-image relationship to the neighboring basic cell.

For example, a P-type diffusion layer Psub <01>, which functions as a sub-region, is provided in a part of the N-type diffusion layer <01> of the source region or non-occupied area in the basic cell BC <01>. P-type impurities, which are different from impurities in the N-type diffusion layer <01>, are doped in the layer Psub <01>.

In addition, an N-type diffusion layer Nsub <01>, which functions as a sub-region, is provided in a part of the P-type diffusion layer <01> of the source region or non-occupied area in the basic cell BC <01>. N-type impurities, which are different from impurities in the P-type diffusion layer <01>, are doped in the layer Nsub <01>. Similarly, layers Psub <21> and Nsub <21> are provided in the basic cell BC <21>. The third embodiment differs from the first and second embodiments in that the diffusion layer of the sub-region is in contact with the diffusion layer of the source region.

In a so-called CMOS structure shown in FIG. 19 which is a cross-sectional view taken along line A-A′ in FIG. 18, there are a parasitic PNP transistor and a parasitic NPN transistor, and the connection state of both transistors is equal to that of an equivalent circuit of a thyristor. However, a voltage VDD is applied to the region Nsub <01> and the P-type diffusion layer <01> in the non-occupied area, thereby equalizing the base-emitter potential of the parasitic PNP transistor and preventing the thyristor from being turned on. The same applies to the other regions Nsub <21>, Psub <01> and Psub <21>. Thus, these regions have the same functions as the sub-regions in the first and second embodiments.

As has been described above, according to the semiconductor integrated circuit device of this embodiment, the same advantageous effects as with the first embodiment can be obtained. Further, for example, the region Nsub <01> is provided in the P-type diffusion layer <01>. Thus, by applying the voltage VDD to the region Nsub <01> and the P-type diffusion layer <01>, the base-emitter potential of the parasitic PNP transistor is equalized to prevent turn-on of the thyristor. Hence, occurrence of so-called latch-up can advantageously be prevented.

The sub-region (Psub, Nsub) is provided in the source region or the diffusion layer functioning as the non-occupied region in one of the transistors of the basic cell BC <01>, BC <21>.

Thus, it should suffice if there is a non-occupied area corresponding to the diffusion layer serving as the source. The entire area of the basic cell BC is not occupied by the sub-region, and microfabrication can advantageously be performed. Further, even in the case where a sub-region is provided in the source region, the diffusion region including the sub-region can be used as a transistor.

It is preferable to provide sub-regions Nsub and Psub at more locations, from the standpoint of preventing potential variation in the well due to carrier injection at a time when the parasitic thyristor is turned on.

Next, a method of manufacturing the semiconductor integrated circuit device according to this embodiment is described.

To start with, using the same fabrication steps as in the first embodiment, N-wells, P-wells and device isolation regions STI are formed in the semiconductor substrate. A polysilicon, for instance, is deposited on the semiconductor substrate by means of, e.g. CVD. Then, the polysilicon is formed to have pattern shapes of gate electrodes, and a gate pattern is formed. A photoresist is coated on the entire surface of the substrate (not illustrated).

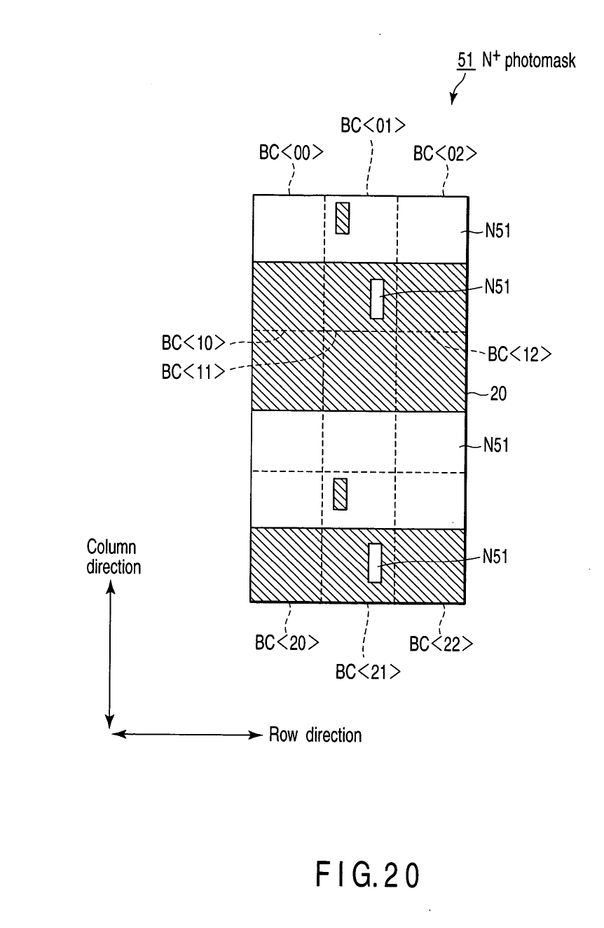

Then, as shown in FIG. 20, an N⁺ photomask 51 is formed and patterned. The N⁺ photomask 51 has, on a glass substrate 20, opening portions N51 corresponding to formation areas of the N-type diffusion layers of the basic cells BC and the sub-regions Nsub <01> and Nsub <21>, and the N⁺ photomask 51 is used to transfer this pattern to the photoresist. When the photomask 51 is formed, there is no need to perform the OPC. In addition, when the ion implantation type is partly reversed as in the case of the ion implantation in the sub-regions Nsub <01> and Nsub <21>, the data for ion implantation is generated to meet design rules.

Using the N⁺ photomask 51 as a mask, the photoresist is subjected to exposure and development, and the pattern of the photomask 51 is transferred to the photoresist.

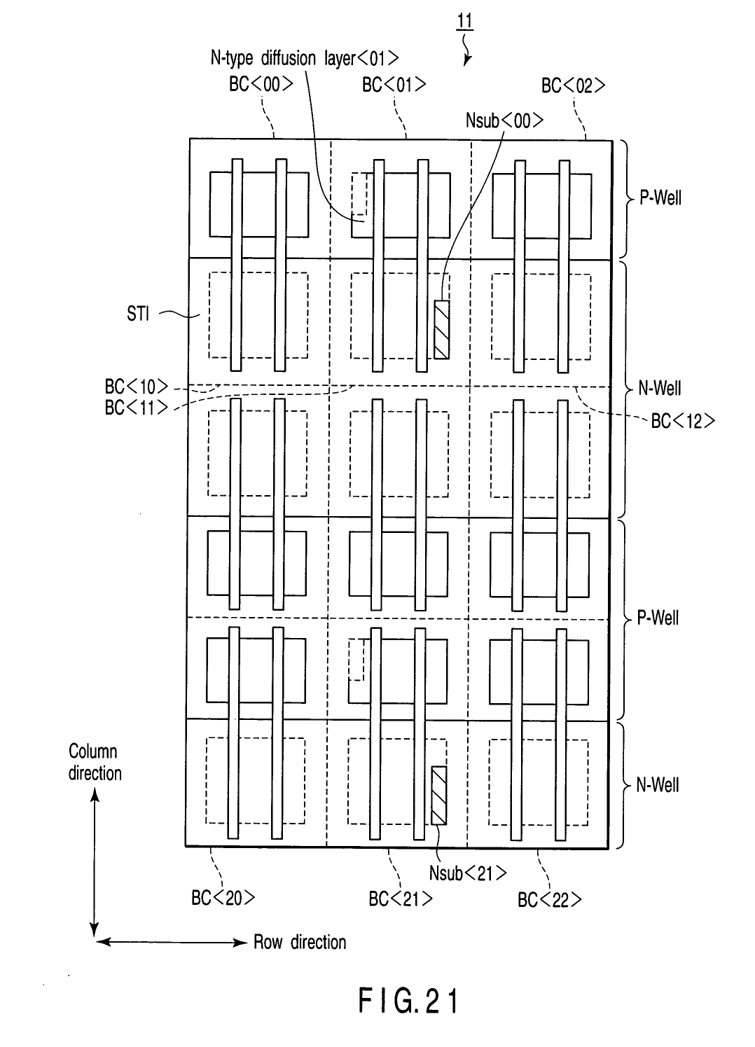

Subsequently, as shown in FIG. 21, using the photoresist with the transferred pattern as a mask, N-type impurities, such as phosphorus (P), are implanted by, e.g. ion implantation, and the implanted impurities are thermally diffused. N-type diffusion layers of the basic cells BC and N-type diffusion layers Nsub <01> and Nsub <21> are formed. The photoresist is then removed.

A photoresist is further coated on the logic circuit structure region 11 (not illustrated).

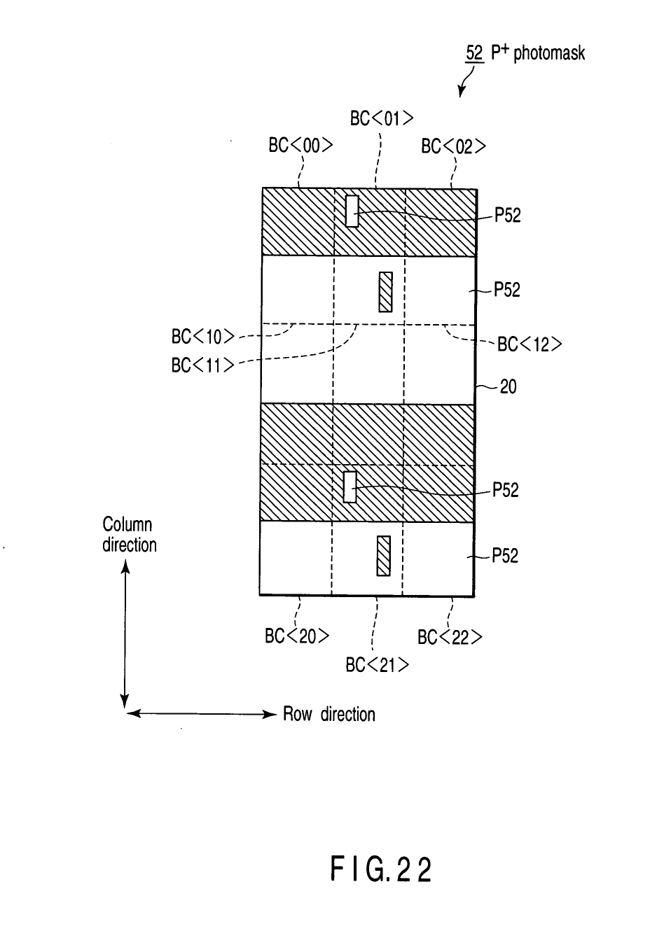

Then, as shown in FIG. 22, a P⁺ photomask 52 is formed and patterned. The P⁺ photomask 52 has, on a glass substrate 20, opening portions P52 corresponding to formation areas of the P-type diffusion layers of the basic cells BC and the sub-regions Psub <01> and Psub <21>, and the P⁺ photomask 52 is used to transfer this pattern to the photoresist. When the photomask 52 is formed, there is no need to perform the OPC. In addition, when the ion implantation type is partly reversed as in the case of the ion implantation in the sub-regions Psub <01> and Psub <21>, the data for ion implantation is generated to meet design rules.

Subsequently, using the photomask 52 as a mask, the photoresist is subjected to exposure and development and the pattern of the photomask 52 is transferred.

Then, using the photoresist with the transferred pattern as a mask, P-type impurities, such as boron (B), are implanted by, e.g. ion implantation, and the implanted impurities are thermally diffused. P-type diffusion layers and sub-regions Psub <01> and Psub <21> are formed. The photoresist is then removed, and the semiconductor integrated circuit device shown in FIG. 18 is fabricated.

According to the semiconductor integrated circuit device of this modification, the same advantageous effects as in the first embodiment can be obtained. Further, when the photomasks 51 and 52 are formed, the data for ion implantation in the non-occupied areas is partly reversed where necessary. Thereby, sub-regions Psub and Nsub, which correspond to circuit alterations, can be formed. Moreover, since the masks 51 and 52 require no OPC, the manufacturing cost can advantageously be reduced.

When the mask 51 is formed, the area of the sub-region Nsub may be increased to become substantially equal to the area of the P-type diffusion layer. Thereby, the sub-region Nsub can be provided not in a part of the P-type diffusion region, but in the entirety of the P-type diffusion region. Similarly, when the mask 52 is formed, the area of the sub-region Psub may be increased to become substantially equal to the area of the N-type diffusion layer. Thereby, the sub-region Psub can be provided not in a part of the N-type diffusion region, but in the entirety of the N-type diffusion region.

### Fourth Embodiment

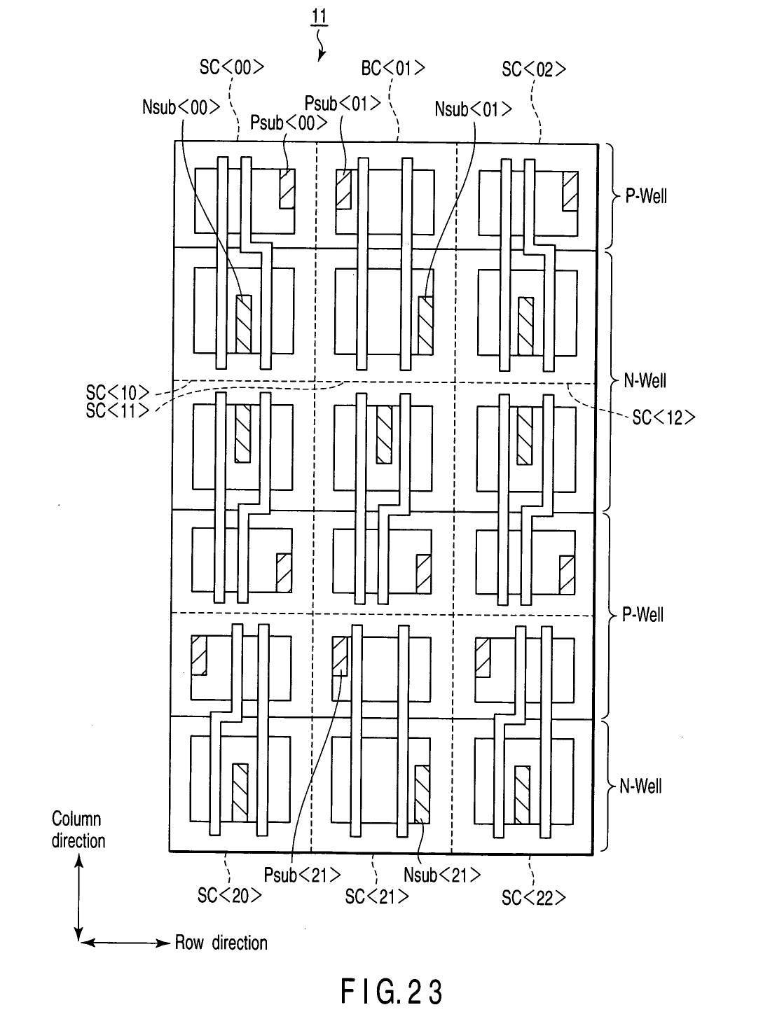

Next, a semiconductor integrated circuit device according to a fourth embodiment of the invention is described referring to FIG. 23. A description of parts common to those of the third embodiment is omitted.

As is shown in FIG. 23, sub-regions (Nsub, Psub) are provided in parts of diffusion layers that serve as sources of arrayed basic cells BC and standard cells SC. The sub-regions have a conductivity type different from the conductivity type of the diffusion layers serving as sources (i.e. the same conductivity type as the wells).

According to the above-described structure, the same advantages as in the third embodiment can be obtained. The above-described structure may be adopted where necessary.

The sub-regions (Nsub, Psub) are provided in parts of diffusion layers that serve as sources of the basic cells BC and standard cells SC. Therefore, it is possible to prevent potential variation in the well due to carrier injection at a time when the parasitic thyristor is turned on, and the occurrence of latch-up can advantageously be prevented.

The method of manufacturing the semiconductor integrated circuit device according to the present embodiment is substantially the same as that in the third embodiment. Thus, a description of the method is omitted here.

The number of gate electrodes in each of the basic cells BC and standard cells SC is not limited to two, and it may be three or more. If the number of gate electrodes is increased, a greater number of transistors can be provided, which is more advantageous for microfabrication.

The sub-region Psub may be provided not in a part of the N-type diffusion layer, but in the entirety of the N-type diffusion layer. Similarly, the sub-region Nsub may be provided not in a part of the P-type diffusion layer, but in the entirety of the P-type diffusion layer.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor integrated circuit device comprising:
cells which are arranged in an array in a logic circuit structure region of a well of a first conductivity type that is provided in a semiconductor substrate, each of the cells including a gate electrode, which is provided on the well, and first diffusion layers of a second conductivity type which are provided in the well such that the first diffusion layers sandwich the gate electrode, the first diffusion layers functioning as sources/drains; and
sub-regions which are arranged in a non-occupied area of the logic circuit structure region, each of the sub-regions including a conductive layer, which is provided on the well and has the same pattern shape as the gate electrode, and second diffusion layers of the first conductivity type, which have the same pattern shape as the first diffusion layers and are disposed spaced apart to sandwich the conductive layer, the second diffusion layers being electrically connected to the well.

2. The semiconductor integrated circuit device according to claim 1, wherein the pattern shapes of the gate electrode and the first diffusion layers of the cell have a mirror-image relationship to a neighboring one of the cells or a neighboring one of the sub-regions.

3. The semiconductor integrated circuit device according to claim 1, wherein the pattern shapes of the conductive layer and the second diffusion layers of the sub-region have a mirror-image relationship to a neighboring one of the cells or a neighboring one of the sub-regions.

4. The semiconductor integrated circuit device according to claim 1, wherein the cells are basic cells having the same pattern shapes of the gate electrodes and the first diffusion layers.

5. The semiconductor integrated circuit device according to claim 4, wherein each of the basic cells includes at least two said gate electrodes.

6. The semiconductor integrated circuit device according to claim 1, wherein the cells are standard cells having at least pattern shapes of the gate electrodes, which are different between the cells or are the same.

7. The semiconductor integrated circuit device according to claim 6, wherein each of the standard cells includes at least two said gate electrodes.

8. A semiconductor integrated circuit device comprising:
cells which are arranged in an array in a logic circuit structure region of a well of a first conductivity type that is provided in a semiconductor substrate, each of the cells including a gate electrode, which is provided on the well, and first diffusion layers of a second conductivity type which are provided in the well such that the first diffusion layers sandwich the gate electrode, the first diffusion layers functioning as sources/drains; and
second diffusion layers of the first conductivity type, which are provided in at least parts of the first diffusion layers functioning as the sources or in at least parts of the first diffusion layers in a non-occupied area, the second diffusion layers being electrically connected to the well and functioning as sub-regions.

9. The semiconductor integrated circuit device according to claim 8, wherein pattern shapes of the gate electrode and the first diffusion layers of the cell have a mirror-image relationship to a neighboring one of the cells.

10. The semiconductor integrated circuit device according to claim 8, wherein the cells are basic cells having the same pattern shapes of the gate electrodes and the first diffusion layers.

11. The semiconductor integrated circuit device according to claim 10, wherein each of the basic cells includes said at least two gate electrodes.

12. The semiconductor integrated circuit device according to claim 8, wherein the cells are standard cells having at least pattern shapes of the gate electrodes, which are different between the cells or are the same.

13. The semiconductor integrated circuit device according to claim 12, wherein each of the standard cells includes said at least two gate electrodes.

14. A method of manufacturing a semiconductor integrated circuit device, comprising:
forming a first well of a first conductivity type and a second well of a second conductivity type in a semiconductor substrate;
forming a first photoresist on the first well and the second well;
forming a first photomask in which a plan-view pattern of a device region corresponding to a sub-region is identical to a plan-view pattern of a device region corresponding to a cell that is to be used as a logic circuit, by executing optical proximity correction;
transferring the patterns of the first photomask to the first photoresist;
performing anisotropic etching on the first well and the second well by using the first photomask with the transferred patterns as a mask, thus forming trenches;
forming device isolation regions by burying insulation films in the trenches;
forming a conductive layer on the first well and the second well;
forming a second photoresist on the conductive layer;
forming a second photomask in which a gate pattern corresponding to the sub-region is identical to a gate pattern corresponding to the cell, by executing optical proximity correction;
transferring the gate patterns of the second photomask to the second photoresist;
performing anisotropic etching down to a level of the first well and the second well by using the second photomask with the transferred gate patterns as a mask, thus leaving the conductive layer on the first well and the second well and forming gate patterns;
forming a first diffusion layer of the first conductivity type, which functions as the sub-region, in a non-occupied area of the first well, and forming a second diffusion layer of the first conductivity type, which functions as a source/drain in the second well; and
forming a third diffusion layer of the second conductivity type, which functions as a source/drain, in the first well, and a fourth diffusion layer of the second conductivity type, which functions as a sub-region in the second well.

15. The method of manufacturing a semiconductor integrated circuit device, according to claim 14, wherein all gate patterns are made identical when the second photomask is formed, and all plan-view patterns of the sources/drains are made identical when the second diffusion layer is formed, thereby forming basic cells.

16. The method of manufacturing a semiconductor integrated circuit device, according to claim 14, wherein all gate patterns are made identical or partly different when the second photomask is formed, and all plan-view patterns of the sources/drains are made identical when the second diffusion layer is formed, thereby forming standard cells.
